(19) United States
(12) Patent Application Publication
(10) Pub. No.: US 2019/0305025 A1
(43) Pub. Date: Oct. 3, 2019

(54) IMAGING PANEL

(71) Applicant: Sharp Kabushiki Kaisha, Sakai City (JP)

(72) Inventor: Hiroyuki MORIWAKI, Sakai City (JP)

(21) Appl. No.: 16/367,311

(22) Filed: Mar. 28, 2019

(30) Foreign Application Priority Data
Mar. 29, 2018 (JP) 2018-064895

(51) Int. Cl. H01L 27/146; G01T 1/202; G01T 1/20

(52) U.S. Cl. CPC H01L 27/14618; H01L 27/14663; G01T 1/2018; G01T 1/202; H01L 27/1462

(57) ABSTRACT

The imaging panel prevents from moisture penetration into the imaging panel without deterioration in detection accuracy of scintillation light and with reduction in production cost. The imaging panel includes an active matrix substrate having pixels each with a photoelectric conversion element, a scintillator provided on a surface of the active matrix substrate, a damp-proof material covering the active matrix substrate and the scintillator, and an adhesive layer bonding the damp-proof material to the scintillator and the active matrix substrate. The active matrix substrate includes a first flattening film provided inside and outside a pixel region and configured as a photosensitive resin film, and an adhesive-filling portion provided in a planar view between a boundary of a scintillator region and the adhesive layer, penetrating from the surface of the active matrix substrate to the first flattening film, and filled with a material same as a material for the adhesive layer.

### TECHNICAL FIELD

The present invention relates to an imaging panel.

### BACKGROUND ART

An X-ray imaging device conventionally includes an active matrix substrate having a photoelectric conversion element provided in each pixel and connected to a switching element. Patent Literature 1 discloses a technique for preventing from moisture penetration into to such an X-ray imaging device. The X-ray imaging device according to Patent Literature 1 prevents from moisture penetration into through an adhesive agent bonding a damp-proof protective layer for a phosphor layer provided on a photoelectric conversion substrate and the photoelectric conversion substrate. Specifically, the photoelectric conversion substrate is provided thereon with a surface organic film made of polyimide or the like, and the surface organic film is provided with a groove that extends along the outer periphery of the phosphor layer and is filled with a resin.

### CITATION LIST

### Patent Literature

Patent Literature 1: JP 6074111 B1

Patent Literature 1 describes providing the photoelectric conversion substrate with the surface organic film having damp-proof effect, and providing the surface organic film with the groove filled with the resin, so that the adhesive agent is less likely to gather and moisture is less likely to enter the photoelectric conversion substrate. This achieves to some extent preventing from moisture penetration into from the photoelectric conversion substrate to the phosphor layer. The surface organic film, which is made of polyimide or the like and has several tens of micrometers in thickness, exhibits the damp-proof effect but absorbs light in a wavelength region of scintillation light to cause deterioration in detection accuracy of the scintillation light. Furthermore, this configuration needs the surface organic film in addition to materials provided on the photoelectric conversion substrate, and thus leads to increase in production cost.

### SUMMARY OF INVENTION

The present invention provides a technique for preventing from moisture penetration into an imaging panel without deterioration in detection accuracy of scintillation light and with reduction in production cost.

In order to achieve the object mentioned above, the present invention provides an imaging panel including: an active matrix substrate having a pixel region provided with a plurality of pixels each including a photoelectric conversion element; a scintillator provided on a surface of the active matrix substrate and configured to convert an X-ray to scintillation light; a damp-proof material covering the active matrix substrate and the scintillator; and an adhesive layer bonding the damp-proof material to the scintillator and the active matrix substrate; in which the active matrix substrate includes a first flattening film provided inside and outside the pixel region and configured as a photosensitive resin film, and an adhesive-filling portion provided in a planar view between the adhesive layer and a boundary of a scintillator region provided with the scintillator, penetrating from the surface of the active matrix substrate to the first flattening film, and filled with a material same as a material for the adhesive layer.

The present invention achieves preventing from moisture penetration into to an imaging panel without deterioration in detection accuracy of scintillation light.

### BRIEF DESCRIPTION OF DRAWINGS

FIG. 1 is a pattern diagram of an X-ray imaging device according to a first embodiment;

FIG. 2 is a pattern diagram showing a schematic configuration of an active matrix substrate in FIG. 1;

FIG. 3 is an enlarged partial plan view of a pixel part provided with a pixel on the active matrix substrate shown in FIG. 2;

FIG. 4A is a sectional view taken along line A-A of the pixel part shown in FIG. 3;

FIG. 4B is a sectional view of a pixel part in an imaging panel shown in FIG. 1;

FIG. 5A is a schematic plan view of the imaging panel shown in FIG. 1;

FIG. 5B is a sectional view taken along line B-B indicated in FIG. 5A;

FIG. 6A is a plan view of an imaging panel according to an application example of the first embodiment;

FIG. 6B is a sectional view of an end region in the imaging panel shown in FIG. 6A;

FIG. 7 is a sectional view of an end region in an imaging panel according to a second embodiment;

FIG. 8A is a sectional view of an end region in an imaging panel according to an application example 1 of the second embodiment;

FIG. 8B is a sectional view of an end region in an imaging panel according to an application example 2 of the second embodiment;

FIG. 8C is a sectional view of an end region in an imaging panel according to an application example 3 of the second embodiment;

FIG. 9 is a sectional view of an end region in an imaging panel according to a third embodiment;

FIG. 10 is a sectional view of an end region in an imaging panel according to an application example 1 of the third embodiment;

FIG. 11A is a sectional view of an end region in an imaging panel according to an application example 2 of the third embodiment;

FIG. 11B is a sectional view of an end region in an imaging panel according to an application example 3 of the third embodiment;

FIG. 12 is a sectional view of an end region in an imaging panel according to an application example 4 of the third embodiment;

FIG. 13A is a sectional view exemplifying an end region in an imaging panel according to a modification example (1);

FIG. 13B is a sectional view exemplifying an end region in an imaging panel different from that shown in FIG. 13A; and

FIG. 13C is a sectional view exemplifying an end region in an imaging panel different from that shown in FIG. 13B.

### DESCRIPTION OF EMBODIMENTS

An imaging panel according to an embodiment of the present invention includes: an active matrix substrate having a pixel region provided with a plurality of pixels each including a photoelectric conversion element; a scintillator provided on a surface of the active matrix substrate and configured to convert an X-ray to scintillation light; a damp-proof material covering the active matrix substrate and the scintillator; and an adhesive layer bonding the damp-proof material to the scintillator and the active matrix substrate; in which the active matrix substrate includes a first flattening film provided inside and outside the pixel region and configured as a photosensitive resin film, and an adhesive-filling portion provided in a planar view between the adhesive layer and a boundary of a scintillator region provided with the scintillator, penetrating from the surface of the active matrix substrate to the first flattening film, and filled with a material same as a material for the adhesive layer (a first configuration).

In the imaging panel according to the first configuration, the scintillator provided on the active matrix substrate is covered with the damp-proof material while the adhesive layer is interposed therebetween. The active matrix substrate includes the first flattening film configured as a photosensitive resin film and provided inside and outside the pixel region. The first flattening film is higher in hygroscopicity than the adhesive layer at high temperature and high humidity, and moisture may enter the active matrix substrate through the first flattening film. The present configuration includes the adhesive-filling portion provided in a planar view between the boundary of the scintillator region and the adhesive layer and piercing from the surface of the active matrix substrate to the first flattening film. The adhesive-filling portion is made of the material same as that for the adhesive layer and is higher in damp-proofness than the first flattening film. Even in a case where moisture enters a lateral end of the first flattening film, the moisture is less likely to penetrate toward the scintillator region. This configuration is less likely to allow moisture penetration into the scintillator from the active matrix substrate to achieve desired detection accuracy.

In the first configuration, optionally, the active matrix substrate further includes a first inorganic film provided inside and outside the pixel region and disposed on a surface, not facing the scintillator, of the first flattening film, and the first inorganic film is provided continuously from the pixel region to a position of the adhesive-filling portion (a second configuration).

According to the second configuration, the first inorganic film is provided on the surface, not facing the scintillator, of the first flattening film and extends continuously from the pixel region to the position of the adhesive-filling portion. In other words, the first inorganic film has no opening. The first inorganic film is higher in damp-proofness than the first flattening film, so that moisture is less likely to enter the first flattening film from the surface, not facing the scintillator, of the first flattening film. This configuration thus achieves higher preventing from moisture penetration into the scintillator.

In the second configuration, optionally, the active matrix substrate further includes a second flattening film provided on a surface, not facing the first flattening film, of the first inorganic film, and configured as a photosensitive resin film, the first inorganic film has a recess penetrating the second flattening film, and the adhesive-filling portion penetrates the first flattening film and is provided continuously to the recess (a third configuration).

According to the third configuration, the second flattening film is provided on the surface, not facing the first flattening film, of the first inorganic film. The first inorganic film has the recess penetrating the second flattening film, and the adhesive-filling portion penetrates the first inorganic film to reach the recess of the first inorganic film. The adhesive-filling portion is provided continuously from the first flattening film to the second flattening film, and has a portion positioned in the second flattening film and covered with the first inorganic film. Even in a case where moisture enters a lateral end of the second flattening film, the moisture is less likely to permeate toward the scintillator region through the adhesive-filling portion. This configuration thus achieves higher preventing from moisture penetration into the scintillator.

In the second configuration, optionally, the active matrix substrate further includes a second flattening film provided on a surface, not facing the first flattening film, of the first inorganic film, and configured as a photosensitive resin film, the first inorganic film has a recess penetrating the second flattening film, the first flattening film covers at least a portion, disposed adjacent to the scintillator region, in an inner wall of the recess of the first inorganic film, and the adhesive-filling portion penetrates the first flattening film and is provided continuously to the recess of the first inorganic film (a fourth configuration).

According to the fourth configuration, the second flattening film is provided on the surface, not facing the first flattening film, of the first inorganic film. The first inorganic film has the recess penetrating the second flattening film, and the first flattening film covers at least the inner wall, adjacent to the scintillator region, of the recess of the first inorganic film. The adhesive-filling portion penetrates the first flattening film to reach the recess of the first inorganic film. The adhesive-filling portion is provided continuously from the first flattening film to the second flattening film, and has a side surface positioned in the second flattening film and adjacent to the scintillator region and covered with the first flattening film and the first inorganic film. Even in a case where moisture enters the lateral end of the second flattening film, the moisture is less likely to permeate toward the scintillator region through the adhesive-filling portion. This configuration thus achieves higher preventing from moisture penetration into the scintillator.

In the second configuration, optionally, the active matrix substrate further includes a second flattening film provided on a surface, not facing the first flattening film, of the first inorganic film, and configured as a photosensitive resin film, and a second inorganic film provided on a surface, facing the scintillator, of the first flattening film, the first inorganic film has a first recess penetrating the second flattening film, the second inorganic film has a second recess penetrating the first flattening film and covering an inner wall of the first recess, and the adhesive-filling portion is provided in the second recess of the second inorganic film (a fifth configuration).

According to the fifth configuration, the second flattening film is provided on the surface, not facing the first flattening film, of the first inorganic film, and the second inorganic film is provided on the surface, facing the scintillator, of the first flattening film. The first inorganic film has the first recess penetrating the second flattening film, and the second inorganic film has the second recess penetrating the first flattening film and overlapped with an interior of the first recess. The adhesive-filling portion is provided in the second recess. The adhesive-filling portion has the side surface positioned in the second flattening film and covered with the second inorganic film and the first inorganic film. Even in a case where moisture enters the lateral end of the second flattening film, the moisture is less likely to permeate toward the scintillator region through the adhesive-filling portion. This configuration thus achieves higher preventing from moisture penetration into the scintillator.

In the second configuration, optionally, the active matrix substrate further includes a second inorganic film provided on a surface, facing the scintillator, of the first flattening film, the second inorganic film has a recess penetrating the first flattening film, and the adhesive-filling portion is provided in the recess of the second inorganic film (a sixth configuration).

According to the sixth configuration, the adhesive-filling portion provided in the recess of the second inorganic film has a surface covered with the second inorganic film. Even in a case where moisture enters the lateral end of the first flattening film configured as a photosensitive resin film, the moisture is less likely to permeate toward the scintillator region through the adhesive-filling portion.

In the sixth configuration, optionally, the active matrix substrate further includes a second flattening film provided to oppose the first flattening film with the first inorganic film being interposed therebetween, and configured as a photosensitive resin film, and a metal film provided between the second flattening film and the first inorganic film, and the metal film is connected to an element provided in the pixel region (a seventh configuration).

According to the seventh configuration, the metal film provided on the second flattening film is covered with the first inorganic film, the second flattening film, and the first inorganic film. This configuration is less likely to allow moisture penetration into the pixel region through the metal film.

In the second configuration, optionally, the active matrix substrate further includes a second flattening film provided on a surface, not facing the first flattening film, of the first inorganic film, and configured as a photosensitive resin film, and a second inorganic film provided on a surface, facing the scintillator, of the first flattening film, the first inorganic film has a first recess penetrating the second flattening film, the first flattening film has a second recess covering at least a portion adjacent to the scintillator region and a portion distant from the scintillator region, in an inner wall of the first recess, the second inorganic film has a third recess covering an inner wall of the second recess, and the adhesive-filling portion is provided in the third recess (an eighth configuration).

According to the eighth configuration, the second flattening film is provided on the surface, not facing the first flattening film, of the first inorganic film, and the second inorganic film is provided on the surface, facing the scintillator, of the first flattening film. The first inorganic film has the first recess reaching the second flattening film, the first flattening film has the second recess overlapped with the interior of the first recess, and the second inorganic film has the third recess overlapped with an interior of the second recess. The adhesive-filling portion is provided in the second inorganic film, the first flattening film, the first inorganic film, and the second flattening film. The adhesive-filling portion has the side surface positioned in the second flattening film and covered with the second inorganic film, the first flattening film, and the first inorganic film. Even in a case where moisture enters the lateral end of the second flattening film, the moisture is less likely to permeate toward the scintillator region through the adhesive-filling portion. This configuration thus achieves higher preventing from moisture penetration into the scintillator.

In any one of the fifth to eighth configurations, optionally, the active matrix substrate further includes a third flattening film provided between the second inorganic film and the scintillator, and configured as a photosensitive resin film, and the third flattening film is disposed at least on the second inorganic film at a position overlapped in a planar view with the scintillator (a ninth configuration).

According to the ninth configuration, the third flattening film is provided on the second inorganic film at the position overlapped in a planar view with the scintillator. This configuration thus achieves more promoted crystal growth of the scintillator in comparison to a case where an inorganic film is not provided at the position overlapped with the scintillator.

In any one of the first to ninth configurations, optionally, the adhesive-filling portion is provided continuously along an outer periphery of the scintillator region (a tenth configuration).

The adhesive-filling portion according to the tenth configuration surrounds the scintillator region. This configuration prevents from moisture penetration into the scintillator even in a case where moisture enters an end of the active matrix substrate.

In any one of the first to tenth configurations, optionally, the imaging panel includes a plurality of adhesive-filling portions configured identically to the adhesive-filling portion, and the adhesive-filling portions are disposed apart from each other in a direction perpendicular to a side of an outer periphery of the scintillator region (an eleventh configuration).

The eleventh configuration achieves higher preventing from moisture penetration into the scintillator in comparison to a case where only one adhesive-filling portion is provided along the outer periphery of the scintillator region.

An embodiment of the present invention will now be described in detail below with reference to the drawings. Identical or corresponding portions in the drawings will be denoted by identical reference signs and will not be described repeatedly.

### First Embodiment

(Configuration)

FIG. 1 is a pattern diagram of an X-ray imaging device including an imaging panel according to the present embodiment. An X-ray imaging device 100 includes an imaging panel 1 having an active matrix substrate 1a and a scintillator 1b, as well as a controller 2.

The controller 2 includes a gate controller 2A and a signal reader 2B. There is provided an X-ray source 3 configured to apply X-rays to a subject S. The X-rays having been transmitted through the subject S are converted to fluorescence (hereinafter, referred to as scintillation light) by the scintillator 1b disposed on the active matrix substrate 1a. The X-ray imaging device 100 captures the scintillation light by means of the imaging panel 1 and the controller 2 to obtain an X-ray image.

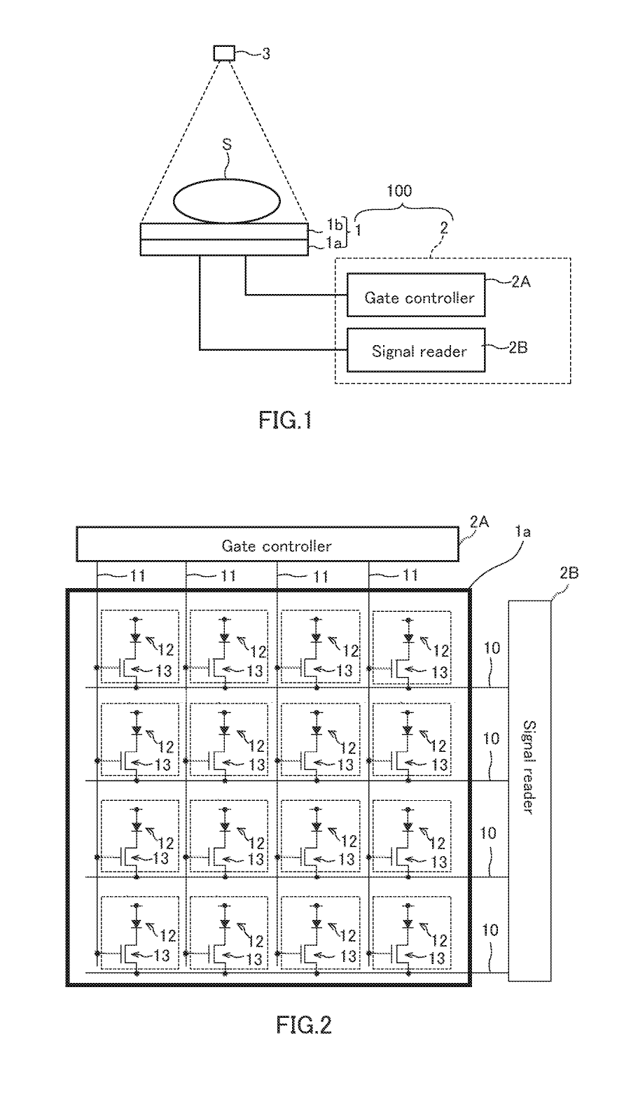

FIG. 2 is a pattern diagram showing a schematic configuration of the active matrix substrate 1a. As shown in FIG. 2, the active matrix substrate 1a is provided with a plurality of source lines 10 and a plurality of gate lines 11 crossing the source lines 10. The gate lines 11 are connected to the gate controller 2A whereas the source lines 10 are connected to the signal reader 2B.

The active matrix substrate 1a includes TFTs 13 positioned at intersections between the source lines 10 and the gate lines 11 and each connected to a corresponding one of the source lines 10 and a corresponding one of the gate lines 11. The source lines 10 and the gate lines 11 surround to define regions (hereinafter, referred to as pixels) that are each provided with a photodiode 12. The photodiode 12 in each of the pixels converts the scintillation light obtained through conversion from the X-rays having been transmitted through the subject S to electric charge according to quantity of the scintillation light.

The gate lines 11 provided at the active matrix substrate 1a are sequentially switched into a selected state by the gate controller 2A, and the TFT 13 connected to the gate line 11 in the selected state is brought into an ON state. When the TFT 13 comes into the ON state, a signal according to the electric charge obtained through conversion by the photodiode 12 is transmitted to the signal reader 2B via the source line 10.

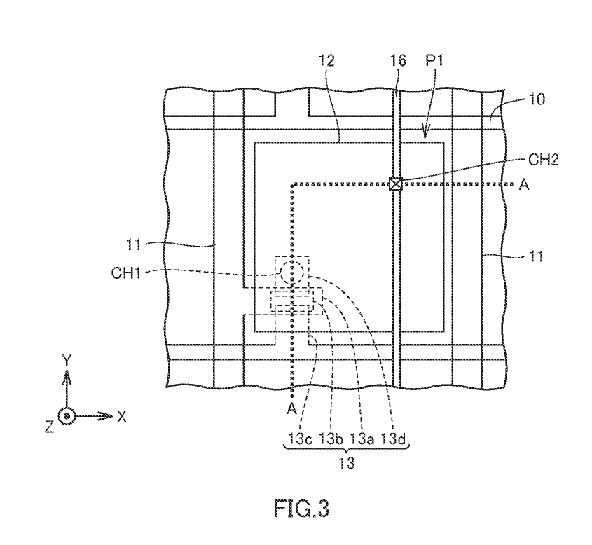

FIG. 3 is an enlarged plan view of part of the pixels at the active matrix substrate 1a shown in FIG. 2.

As shown in FIG. 3, the gate lines 11 and the source lines 10 surround a pixel P1 provided with the photodiode 12 and the TFT 13.

The photodiode 12 includes a pair of electrodes and a photoelectric conversion layer provided between the pair of electrodes. The TFT 13 includes a gate electrode 13a provided integrally with the gate line 11, a semiconductor active layer 13b, a source electrode 13c provided integrally with the source line 10, and a drain electrode 13d. The drain electrode 13d and one of the electrodes of the photodiode 12 are connected to each other via a contact hole CH1.

The gate electrode 13a or the source electrode 13c may not necessarily be provided integrally with the gate line 11 or the source line 10, respectively. Alternatively, the gate electrode 13a and the gate line 11 may be disposed in different layers and be connected to each other via a contact hole. Furthermore, the source electrode 13c and the source line 10 may be disposed in different layers and be connected to each other via a contact hole. Such a configuration achieves reduction in resistance of the gate line 11 and the source line 10.

There is provided a bias line 16 overlapped with the photodiode 12 in the pixel, and the photodiode 12 and the bias line 16 are connected to each other via a contact hole CH2. The bias line 16 is configured to supply the photodiode 12 with bias voltage.

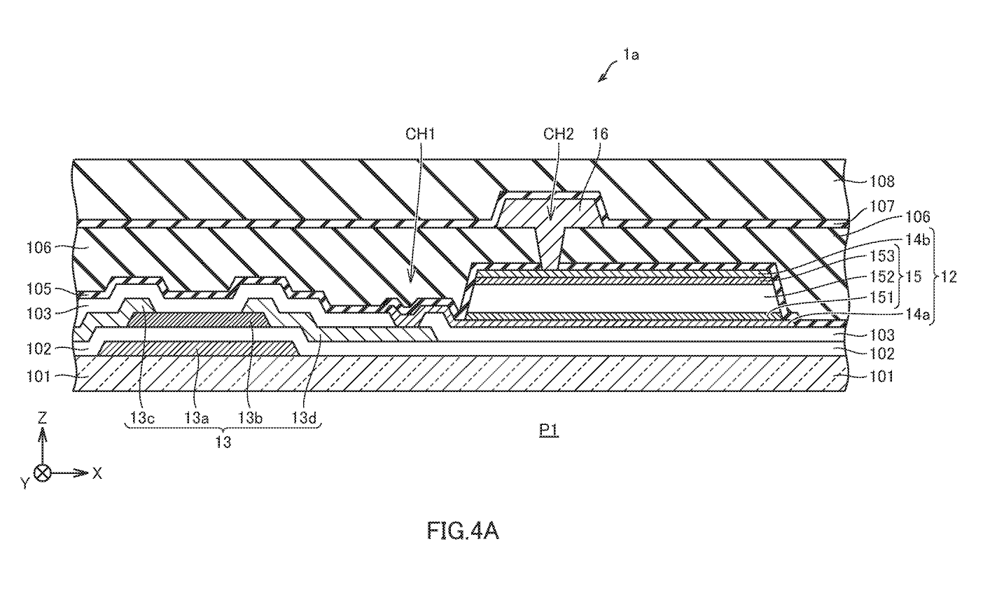

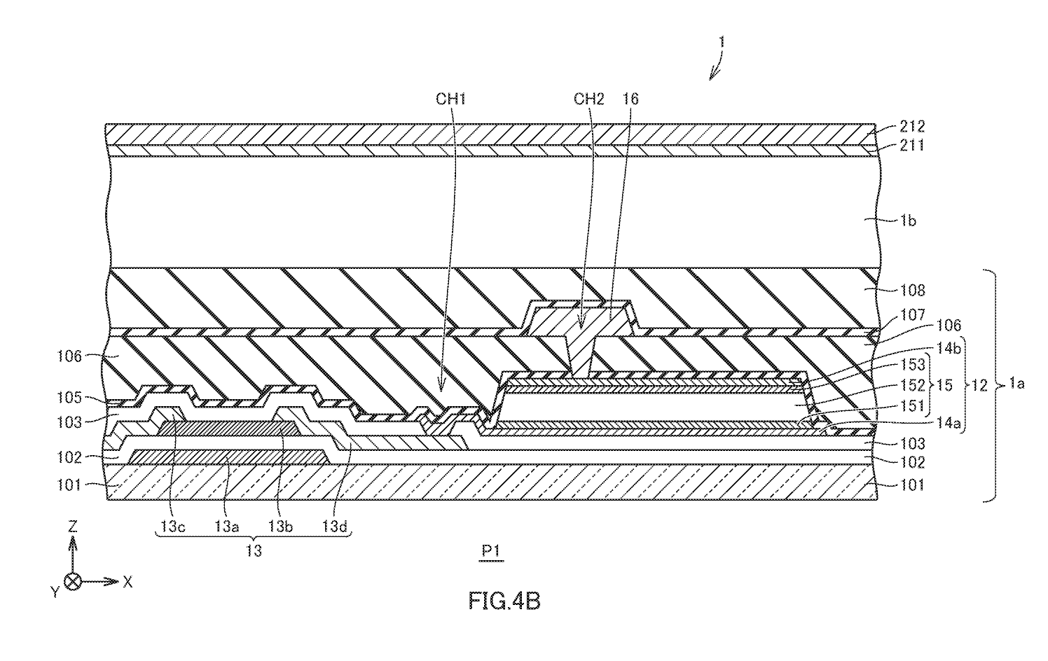

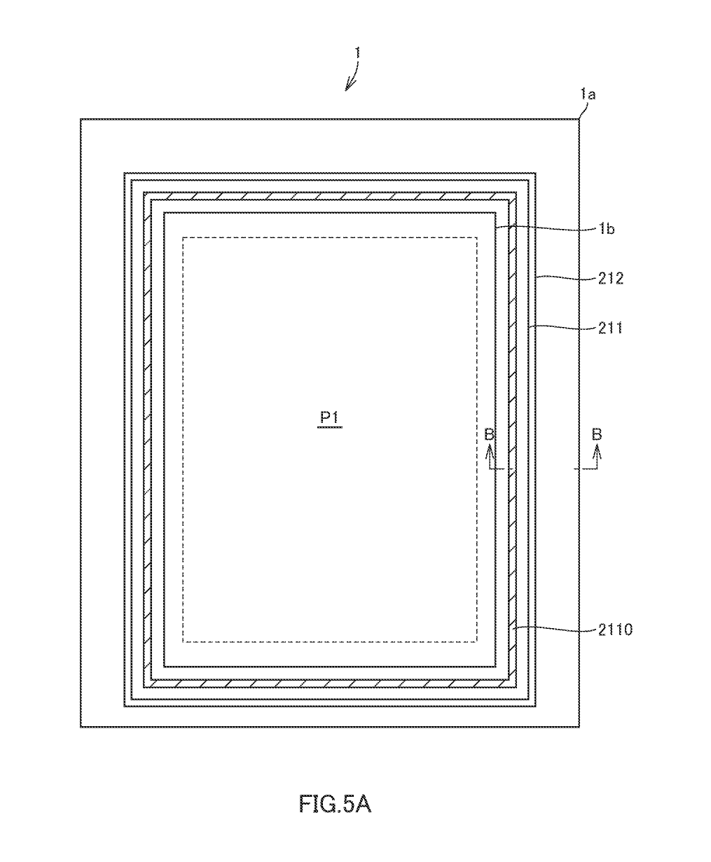

The pixel P1 will be described below in terms of a sectional structure taken along line A-A. FIG. 4A is a sectional view taken along line A-A of the pixel P1 shown in FIG. 3. FIG. 4A shows a substrate 101 provided thereon with the gate electrode 13a integrated with the gate line 11 (see FIG. 3), and a gate insulating film 102. The substrate 101 exhibits insulation effect and is configured as a glass substrate or the like.

The gate electrode 13a and the gate line 11 according to the present example may be configured as a metal film including tungsten (W) and tantalum (Ta) layered in the mentioned order from the bottom, and having about 100 nm to 1000 nm in thickness. Each of the gate electrode 13a and the gate line 11 is not limited to such a two-layer structure, but may alternatively have a single layer or a plurality of layers including at least two layers and is not limited to the above exemplification in terms of its material and thickness.

The gate insulating film 102 covers the gate electrode 13a. The gate insulating film 102 according to the present example has a layered structure including two inorganic insulating films. The two inorganic insulating films may be made of silicon nitride (SiNₓ) and silicon oxide (SiOₓ) in the mentioned order from the bottom. The gate insulating film 102 is preferred to have about 100 nm to 1000 nm in thickness. The gate insulating film 102 is not limited to such a two-layer structure, but may alternatively have a single layer or a plurality of layers including at least two layers. The gate insulating film 102 is not limited to the above exemplification in terms of its material and thickness.

The gate electrode 13a is provided thereabove, while the gate insulating film 102 is interposed therebetween, with the semiconductor active layer 13b, as well as the source electrode 13c and the drain electrode 13d connected to the semiconductor active layer 13b.

The semiconductor active layer 13b is disposed in contact with the gate insulating film 102. The semiconductor active layer 13b is made of an oxide semiconductor. The oxide semiconductor is exemplified by an amorphous oxide semiconductor containing indium (In), gallium (Ga), and zinc (Zn) at predetermined ratios. The semiconductor active layer 13b is preferred to exemplarily have about 100 nm in thickness in this case. The semiconductor active layer 13b is, however, not limited to the above exemplification in terms of its material and thickness.

The source electrode 13c and the drain electrode 13d are disposed on the gate insulating film 102 and are in contact with part of the semiconductor active layer 13b. The source electrode 13c according to the present example is provided integrally with the source line 10 (see FIG. 3). The source electrode 13c and the drain electrode 13d have a layered structure including three metal films. The three metal films may be made of titanium (Ti), aluminum (Al), and titanium (Ti) in the mentioned order from the bottom. The source electrode 13c and the drain electrode 13d are preferred to exemplarily have about 100 nm to 1000 nm in thickness in this case. Each of the source electrode 13c and the drain electrode 13d is not limited to such a three-layer structure, but may alternatively have a single layer or a plurality of layers including at least two layers. Each of the source electrode 13c and the drain electrode 13d is not limited to the above exemplification in terms of its material and thickness.

The gate insulating film 102 is provided thereon with a first insulating film 103 that is overlapped with the source electrode 13c and the drain electrode 13d. The first insulating film 103 has the contact hole CH1 positioned above the drain electrode 13d. The first insulating film 103 according to the present example has a layered structure including two inorganic insulating films. The two inorganic insulating films may be made of silicon dioxide (SiO₂) and silicon nitride (SiN) in the mentioned order from the bottom. The first insulating film 103 is preferred to have about 100 nm to 1000 nm in thickness in this case. The first insulating film 103 is not limited to such a two-layer structure, but may alternatively have a single layer or a plurality of layers including at least two layers. The first insulating film 103 configured by a single layer is made only of silicon dioxide (SiO₂). The first insulating film 103 is not limited to the above exemplification in terms of its material and thickness.

The first insulating film 103 is provided thereon with one of the electrodes (hereinafter, called a lower electrode) 14a of the photodiode 12, and a second insulating film 105. The lower electrode 14a is connected to the drain electrode 13d via the contact hole CH1.

The lower electrode 14a according to the present example has a layered structure including three metal films. The three metal films may exemplarily be made of titanium (Ti), aluminum (Al), and titanium (Ti) in the mentioned order from the bottom. The lower electrode 14a is preferred to have about 100 nm to 1000 nm in thickness in this case. The lower electrode 14a is not limited to such a three-layer structure, but may alternatively have a single layer or a plurality of layers including at least two layers. The lower electrode 14a is not limited to the above exemplification in terms of its material and thickness.

The lower electrode 14a is provided thereon with a photoelectric conversion layer 15, and the lower electrode 14a and the photoelectric conversion layer 15 are connected to each other.

The photoelectric conversion layer 15 includes an n-type amorphous semiconductor layer 151, an intrinsic amorphous semiconductor layer 152, and a p-type amorphous semiconductor layer 153 layered in the mentioned order.

The n-type amorphous semiconductor layer 151 is made of amorphous silicon doped with an n-type impurity (e.g. phosphorus).

The intrinsic amorphous semiconductor layer 152 is made of intrinsic amorphous silicon. The intrinsic amorphous semiconductor layer 152 is provided in contact with the n-type amorphous semiconductor layer 151.

The p-type amorphous semiconductor layer 153 is made of amorphous silicon doped with a p-type impurity (e.g. boron). The p-type amorphous semiconductor layer 153 is provided in contact with the intrinsic amorphous semiconductor layer 152.

The n-type amorphous semiconductor layer 151, the intrinsic amorphous semiconductor layer 152, and the p-type amorphous semiconductor layer 153 according to the present example are preferred to exemplarily have about 1 nm to 100 nm, about 500 nm to 2000 nm, and about 1 nm to 100 nm in thickness, respectively. Each of the n-type amorphous semiconductor layer 151, the intrinsic amorphous semiconductor layer 152, and the p-type amorphous semiconductor layer 153 is not limited to the above exemplification in terms of its dopant and thickness.

The p-type amorphous semiconductor layer 153 is provided thereon with another one of the electrodes (hereinafter, called an upper electrode) 14b of the photodiode 12. The upper electrode 14b is exemplarily configured by a transparent conductive film made of indium tin oxide (ITO). The upper electrode 14b is preferred to exemplarily have about 10 nm to 100 nm in thickness in this case. The upper electrode 14b is, however, not limited to the above exemplification in terms of its material and thickness.

The second insulating film 105 is provided on the first insulating film 103, the lower electrode 14a, and the upper electrode 14b, and a third insulating film 106 is provided on the second insulating film 105. The contact hole CH2 is positioned on the upper electrode 14b and penetrates the second insulating film 105 and the third insulating film 106.

The second insulating film 105 according to the present example is configured as an inorganic insulating film made of silicon dioxide (SiO₂) or silicon nitride (SiN). The second insulating film 105 is preferred to exemplarily have about 100 nm to 1000 nm in thickness in this case. The second insulating film 105 is, however, not limited to the above exemplification in terms of its material and thickness. The third insulating film 106 is preferred to be configured as a flattening film made of a photosensitive acrylic resin and exemplarily have about 1.0 μm to 3.0 μm in thickness. The third insulating film 106 is, however, not limited to the above exemplification in terms of its material and thickness.

The third insulating film 106 is provided thereon with the bias line 16 that is connected to the upper electrode 14b via the contact hole CH2. The bias line 16 is connected to the controller 2 (see FIG. 1). The bias line 16 applies, to the upper electrode 14b, bias voltage received from the controller 2.

The bias line 16 according to the present example has a layered structure including a metal layer as a lower layer and a transparent conductive layer as an upper layer. The metal layer may include layered films exemplarily made of titanium (Ti), aluminum (Al), and titanium (Ti), and the transparent conductive layer may be exemplarily made of ITO or the like. The bias line 16 is preferred to have about 100 nm to 1000 nm in thickness. The bias line 16 may have a single layer or a plurality of layers including at least two layers. The bias line 16 is not limited to the above exemplification in terms of its material and thickness.

The third insulating film 106 is provided thereon with a fourth insulating film 107 that covers the bias line 16. The fourth insulating film 107 according to the present example may be configured as an inorganic insulating film made of silicon nitride (SiNₓ), and is preferred to exemplarily have about 100 nm to 1000 nm in thickness. The fourth insulating film 107 may have a single layer structure including the single inorganic insulating film, or a layered structure including a plurality of inorganic insulating films. The fourth insulating film 107 is not limited to the above exemplification in terms of its material and thickness.

The fourth insulating film 107 is covered with a fifth insulating film 108. The fifth insulating film 108 is preferred to be configured as a flattening film made of a photosensitive resin and exemplarily have about 1.0 μm to 10.0 μm in thickness. The fifth insulating film 108 is, however, not limited to the above exemplification in terms of its material and thickness.

The active matrix substrate 1a has the sectional structure described above in the single pixel P1. The scintillator 1b is provided on the active matrix substrate 1a in the imaging panel 1. FIG. 4B is a sectional view showing a sectional structure of a pixel region in the imaging panel 1. As shown in FIG. 4B, the active matrix substrate 1a is provided thereon with the scintillator 1b covering the fifth insulating film 108, and there is provided a damp-proof material 212 that covers the scintillator 1b and is bonded to the scintillator 1b by means of an adhesive layer 211. The adhesive layer 211 is made of a photosetting resin, a thermosetting resin, a hot melt resin, or the like, and exhibits damp-proof effect. The damp-proof material 212 is exemplarily configured by an organic film having damp-proofness.

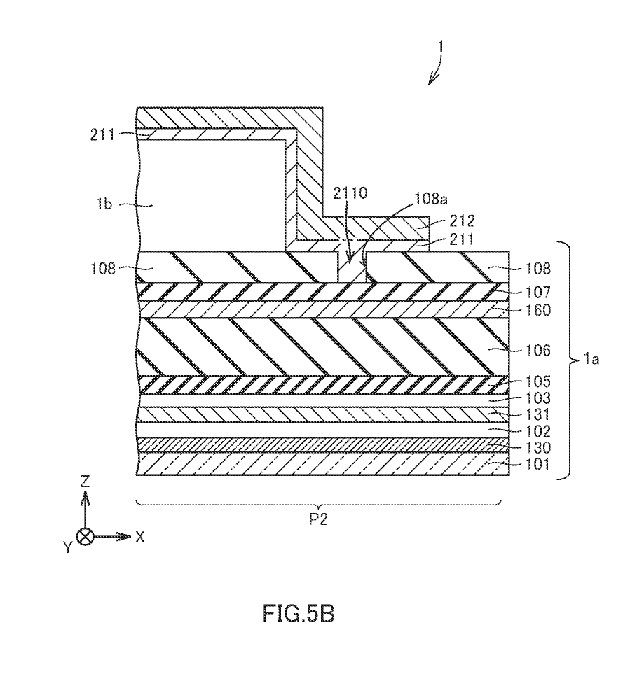

Described next is a structure outside the entire pixel region in the imaging panel 1, in other words, a structure of an end region in the imaging panel 1. FIG. 5A is a schematic plan view of the imaging panel 1, and FIG. 5B is a sectional view taken along line B-B indicated in FIG. 5A and showing an enlarged section of part of an end region P2 along a side of the active matrix substrate 1a.

In FIGS. 5A and 5B, components identical to those shown in FIG. 4B are denoted by identical reference signs. The end region P2 will be specifically described below in terms of its structure. FIG. 5B shows the section of the end region along one of the sides of the active matrix substrate 1a for convenience. The remaining sides are each assumed to have an end region configured similarly to that shown in FIG. 5B.

As shown in FIG. 5B, the end region P2 includes a gate layer 130 provided on the substrate 101 to be disposed in a layer including the gate electrode 13a, be made of the material same as that for the gate electrode 13a, and be provided thereon with the gate insulating film 102. The gate insulating film 102 is provided thereon with a source layer 131 that is disposed in a layer including the source electrode 13c and the drain electrode 13d, and is made of the material same as that for the source electrode 13c and the drain electrode 13d. The gate layer 130 is connected, via a contact hole (not shown), to a gate terminal (not shown) provided outside the pixel region of the active matrix substrate 1a. The source layer 131 is connected, via a contact hole (not shown), to a source terminal (not shown) provided outside the pixel region of the active matrix substrate 1a.

The first insulating film 103 is provided on the source layer 131, the second insulating film 105 is provided on the first insulating film 103, and the third insulating film 106 is provided on the second insulating film 105. The third insulating film 106 is provided thereon with a bias line layer 160 that is disposed in a layer including the bias line 16 and is made of the material same as that for the bias line 16.

Each of the gate layer 130, the source layer 131, and the bias line layer 160 may be extended from the pixel region to the end region. Outside the pixel region, a metal film provided in a layer not including the gate line 11, the source line 10, or the bias line 16 may be connected to each of these lines via a contact hole.

The bias line layer 160 is provided thereon with the fourth insulating film 107 that is provided thereon with the fifth insulating film 108 having a separated portion on the fourth insulating film 107.

The fifth insulating film 108 is provided thereon with the scintillator 1b that is provided thereon with the damp-proof material 212 bonded to the scintillator 1b by means of the adhesive layer 211.

Separation of the fifth insulating film 108 configures an opening 108a that is filled with a material for the adhesive layer 211 to configure an adhesive-filling portion 2110.

As shown in FIG. 5A, the adhesive-filling portion 2110 is disposed between a boundary of a scintillator region provided with the scintillator 1b and the adhesive layer 211, and extends along an outer periphery of the scintillator region. The fifth insulating film 108 configured as a photosensitive resin film is likely to absorb moisture at high temperature and high humidity. The adhesive-filling portion 2110 exhibits excellent damp-proof effect to prevent from moisture penetration into an end of the fifth insulating film 108, so that the moisture is less likely to penetrate the scintillator region.

The adhesive-filling portion 2110 has a bottom of length, along an X axis, which is preferred to be three to ten times of height (along a Z axis) of the fifth insulating film 108. The opening 108a in the fifth insulating film 108 has width (length along the X axis) which is preferred to be larger at a portion adjacent to the fourth insulating film 107 and be smaller at a portion adjacent to the scintillator 1b. Such a configuration achieves increase in contact area between the adhesive-filling portion 2110 and the fourth insulating film 107 as well as improvement in adhesiveness.

Each of the layers provided in the end region P2 according to the present embodiment is made of the material same as that for a corresponding one of the layers provided in the pixel P1. The end region P2 can thus be prepared simultaneously with the pixel P1. Accordingly, the adhesive-filling portion 2110 can be prepared without increase in the number of production steps.

(Operation of X-Ray Imaging Device 100)

The X-ray imaging device 100 shown in FIG. 1 will be described below in terms of its operation. The X-ray source 3 initially emits X-rays. The controller 2 applies predetermined voltage (bias voltage) to the bias line 16 (see FIG. 3) in this case. The X-rays emitted from the X-ray source 3 are transmitted through the subject S and enter the scintillator 1b. The X-rays having entered the scintillator 1b are converted to fluorescence (scintillation light) that subsequently enters the active matrix substrate 1a. When the scintillation light enters the photodiode 12 provided in each of the pixels of the active matrix substrate 1a, the photodiode 12 converts the scintillation light to electric charge according to quantity of the scintillation light. When the TFT 13 (see FIG. 3 and the like) is in the ON state in accordance with gate voltage (positive voltage) transmitted from the gate controller 2A via the gate line 11, the signal reader 2B (see FIG. 2 and the like) reads, via the source line 10, a signal according to the electric charge obtained through conversion by the photodiode 12. The controller 2 then generates an X-ray image according to the read signal.

### Application Example

The first embodiment exemplifies the imaging panel 1 including the single adhesive-filling portion. The imaging panel may alternatively have a plurality of adhesive-filling portions.

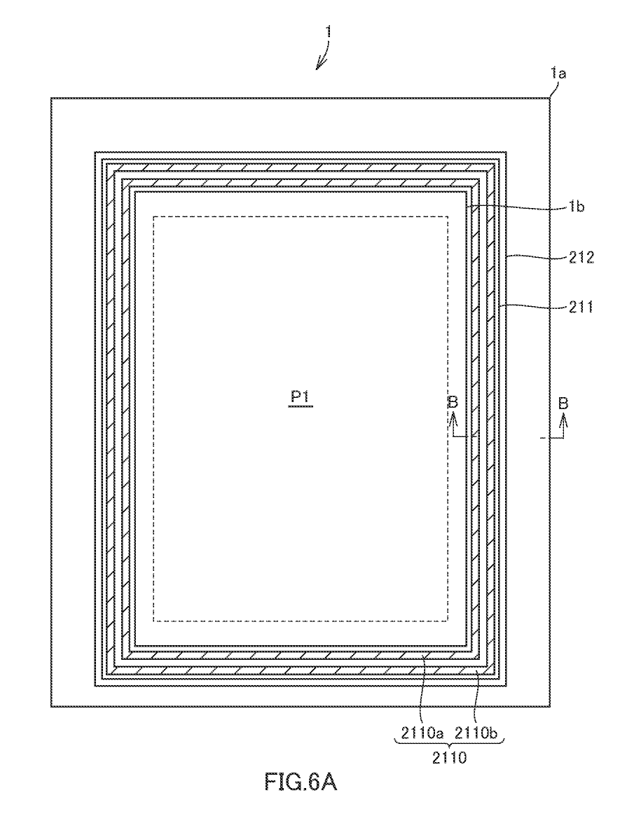

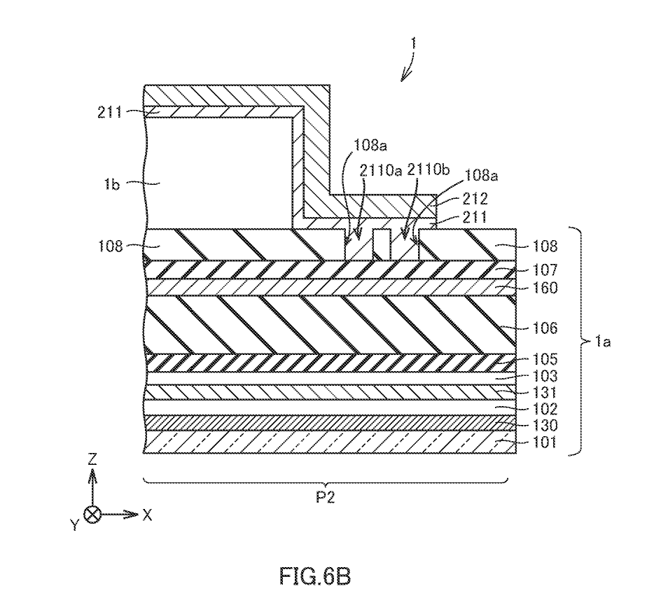

FIG. 6A is a plan view of an imaging panel according to the present application example, and FIG. 6B is a sectional view taken along line B-B indicated in FIG. 6A and showing a section of the end region P2 in the imaging panel. As shown in FIGS. 6A and 6B, the imaging panel 1 according to the present application example includes adhesive-filling portions 2110a and 2110b provided between the boundary of the scintillator region and the adhesive layer 211 and each structured identically to the adhesive-filling portion 2110 according to the first embodiment. As shown in FIG. 6A, the adhesive-filling portions 2110a and 2110b are disposed along the outer periphery of the scintillator region.

The two adhesive-filling portions provided in the fifth insulating film 108 and between the boundary of the scintillator region and the adhesive layer 211 achieve higher preventing from moisture penetration into the scintillator 1b from the end of the fifth insulating film 108 in comparison to the case of providing a single adhesive-filling portion.

### Second Embodiment

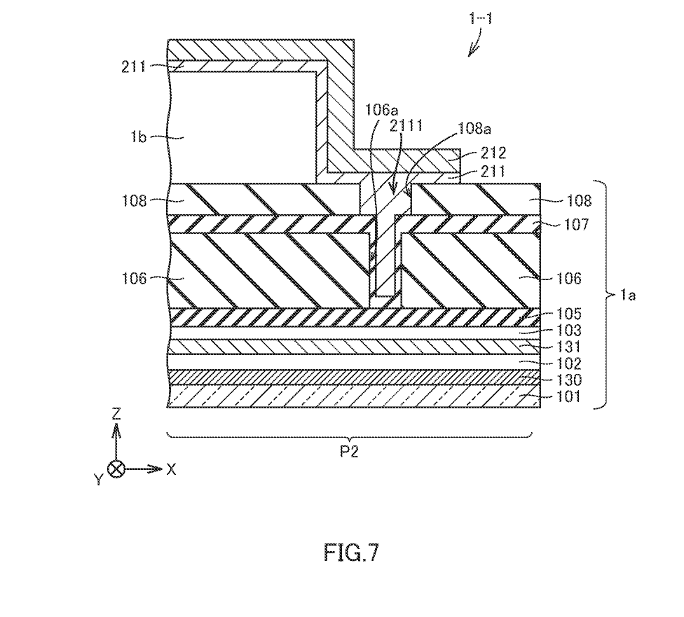

The present embodiment will refer to a structure of an adhesive-filling portion different from that according to the first embodiment. FIG. 7 is a sectional view of the end region P2 in an imaging panel according to the present embodiment. In FIG. 7, components identical to those according to the first embodiment are denoted by identical reference signs. Components different from those according to the first embodiment will be mainly described below.

FIG. 7 shows an imaging panel 1-1 different from the imaging panel according to the first embodiment in that the active matrix substrate 1a does not include the bias line layer 160.

Furthermore, the third insulating film 106 according to the present embodiment has an opening 106a that is positioned to be overlapped in a planar view with the opening 108a in the fifth insulating film 108 and is smaller in opening width than the opening 108a in the fifth insulating film 108, and the fourth insulating film 107 is provided along an inner wall of the opening 106a in the third insulating film 106. The fourth insulating film 107 has a depression (recess) penetrating the third insulating film 106 and connected to the opening 108a in the fifth insulating film 108. The opening 108a in the fifth insulating film 108 and the depression of the fourth insulating film 107 are filled with the material for the adhesive layer 211 to configure an adhesive-filling portion 2111.

The third insulating film 106, which is configured as a photosensitive resin film similarly to the fifth insulating film 108, is likely to absorb moisture. The adhesive-filling portion 2111 according to the present embodiment is provided between the boundary of the scintillator region and the adhesive layer 211 and in the fifth insulating film 108, the fourth insulating film 107, and the third insulating film 106, and has a surface positioned in the third insulating film 106 and covered with the fourth insulating film 107 configured as an inorganic insulating film. Even in a case where moisture enters an end of the third insulating film 106, the moisture is less likely to permeate toward the scintillator 1b. This configuration thus achieves higher preventing from moisture penetration into the scintillator 1b.

### Application Example 1

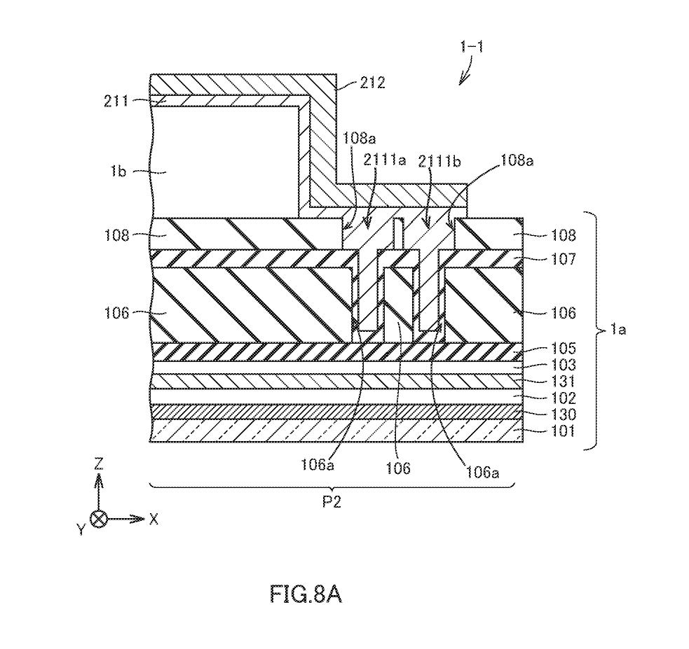

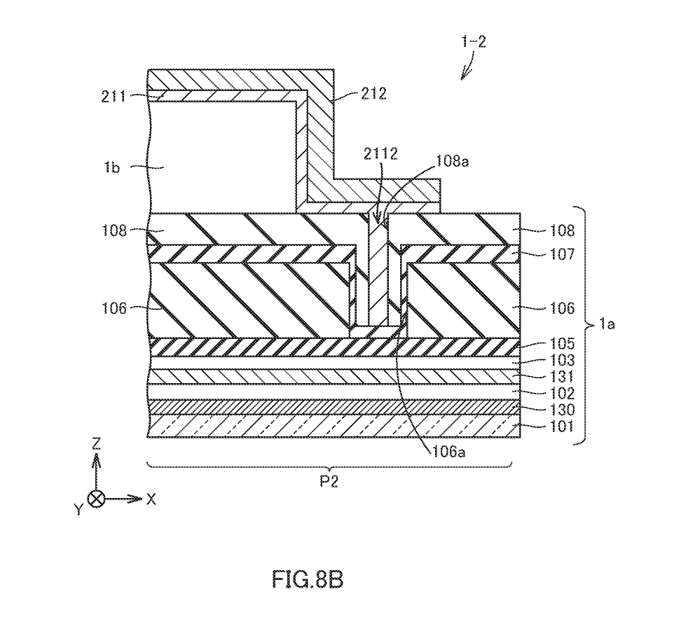

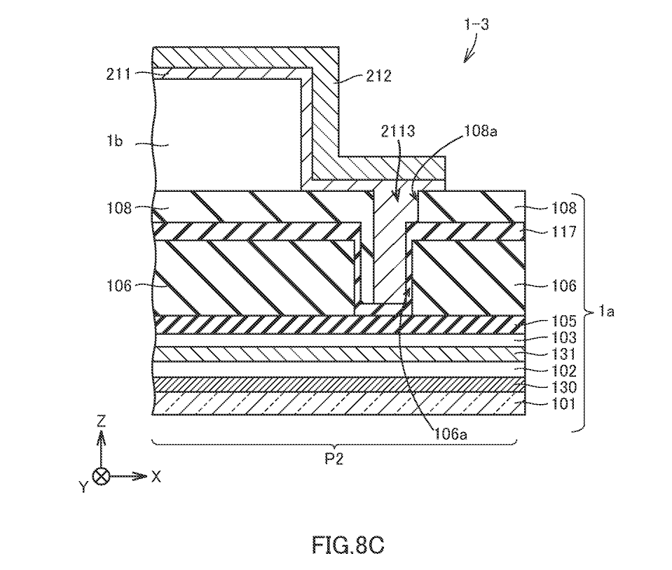

The second embodiment described above provides the imaging panel 1-1 including the single adhesive-filling portion 2111. The imaging panel may alternatively have a plurality of adhesive-filling portions 2111 disposed between the boundary of the scintillator region and the adhesive layer 211, as in FIG. 6A. FIG. 8A is a sectional view of the end region P2 in an imaging panel according to the present application example.

As shown in FIG. 8A, the present application example 1 provides an imaging panel 1-2 including the active matrix substrate 1a provided with adhesive-filling portions 2111a and 2111b configured identically to the adhesive-filling portion 2111 according to the second embodiment and disposed apart from each other.

Such provision of the plurality of adhesive-filling portions 2111a and 2111b achieves higher preventing from moisture penetration into the scintillator 1b from the ends of the fifth insulating film 108 and the third insulating film 106, in comparison to the configuration according to the second embodiment.

### Application Example 2

FIG. 8B is a sectional view of the end region P2 in an imaging panel 1-3 according to the present application example. In FIG. 8B, components identical to those according to the second embodiment are denoted by identical reference signs. Components different from those according to the second embodiment will be described below.

As shown in FIG. 8B, the fourth insulating film 107 according to the present application example is provided along the inner wall of the opening 106a in the third insulating film 106 so as to configure the depression of the fourth insulating film 107. The fifth insulating film 108 is provided on the fourth insulating film 107 to cover an inner wall, except a bottom, of the depression of the fourth insulating film 107, and has the opening 108a disposed inside the depression of the fourth insulating film 107. The opening 108a in the fifth insulating film 108 is filled with an adhesive agent for the adhesive layer 211 to configure an adhesive-filling portion 2112. The adhesive-filling portion 2112 penetrates the fifth insulating film 108 to reach the bottom of the depression of the fourth insulating film 107.

Accordingly, the fifth insulating film 108 and the fourth insulating film 107 cover a surface of the adhesive-filling portion 2112 in the fourth insulating film 107 and cover a side surface of the adhesive-filling portion 2112 in the third insulating film 106, and the fourth insulating film 107 covers a bottom of the adhesive-filling portion 2112.

The opening 108a in the fifth insulating film 108 according to the present example penetrates to reach the bottom of the depression of the fourth insulating film 107. The fifth insulating film 108 may alternatively have an opening provided to leave the fifth insulating film 108 in the depression of the fourth insulating film 107. The bottom of the adhesive-filling portion 2112 is covered with the fifth insulating film 108 and the fourth insulating film 107 in this case.

The adhesive-filling portion 2112 according to the present application example has the side surface positioned in the third insulating film 106 and covered with two layers, namely, the fifth insulating film 108 and the fourth insulating film 107. Even in a case where moisture enters the end of the third insulating film 106, the moisture is less likely to permeate the third insulating film 106. This configuration thus achieves higher preventing from moisture penetration into the scintillator 1b, in comparison to the configuration according to the second embodiment.

Although not shown herein, there may alternatively be provided a plurality of adhesive-filling portions 2112 between the boundary of the scintillator region and the adhesive layer 211 so as to be spaced apart from each other, as in FIG. 6A. Such a configuration prevents from moisture penetration into the scintillator 1b more effectively.

### Application Example 2-1

The application example 2 described above exemplifies the case where, in the adhesive-filling portion 2112 positioned in the fourth insulating film 107 and the third insulating film 106, the fifth insulating film 108 covers the side surface adjacent to the scintillator 1b and the side surface opposed thereto, that is, the side surface adjacent to an end of the active matrix substrate 1a. The fifth insulating film 108 may alternatively cover only one of these side surfaces.

FIG. 8C is a sectional view showing a structure of an adhesive-filling portion in an imaging panel according to the present application example. In FIG. 8C, components identical to those according to the application example 2 of the second embodiment are denoted by identical reference signs.

As shown in FIG. 8C, in the imaging panel 1-3, the fifth insulating film 108 covers a side surface, adjacent to the scintillator 1b, of an adhesive-filling portion 2113 positioned in the fourth insulating film 107 and the third insulating film 106. In contrast, the fifth insulating film 108 does not cover a side surface, adjacent to the end of the active matrix substrate 1a, of the adhesive-filling portion 2113 positioned in the fourth insulating film 107 and the third insulating film 106.

At least the side surface, adjacent to the scintillator 1b, of the adhesive-filling portion 2113 positioned in the third insulating film 106 is covered with two layers, namely, the fifth insulating film 108 and the fourth insulating film 107. Even in a case where moisture enters the end of the third insulating film 106, the moisture is less likely to permeate the third insulating film 106 toward the scintillator 1b. This configuration thus achieves preventing from moisture penetration into the scintillator 1b.

Although not shown herein, there may alternatively be provided a plurality of adhesive-filling portions 2113 between the boundary of the scintillator region and the adhesive layer 211 so as to be spaced apart from each other, as in FIG. 6A. Such a configuration prevents from moisture penetration into the scintillator 1b more effectively.

### Third Embodiment

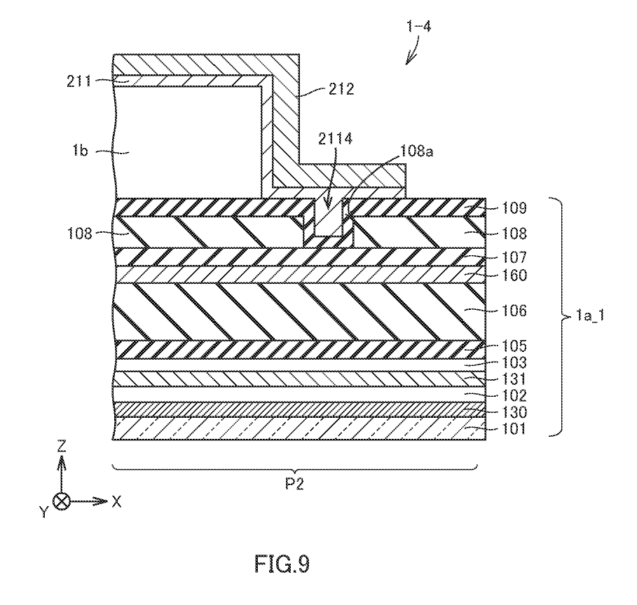

FIG. 9 is a sectional view showing a configuration of an imaging panel according to the present embodiment. In FIG. 9, components identical to those according to the first embodiment are denoted by identical reference signs. Components different from those according to the first embodiment will be mainly described below.

As shown in FIG. 9, the present embodiment provides an imaging panel 1-4 including an active matrix substrate 1a_1 in place of the active matrix substrate 1a.

The active matrix substrate 1a_1 has the end region P2 including the bias line layer 160 that is disposed between the fourth insulating film 107 and the third insulating film 106, is configured as a metal film, and is electrically connected to the bias line 16. Although not shown in this figure, the end region P2 in the active matrix substrate 1a_1 includes a terminal configured to supply the bias line 16 with bias voltage and connected to the bias line layer 160. The bias line layer 160 may be provided by extending the bias line 16 from the pixel P1 to the end region P2, or may be provided in a layer not including the bias line 16 in the pixel P1 and be connected to the bias line 16 via a contact hole (not shown).

The active matrix substrate 1a_1 further includes a sixth insulating film 109 provided on the fifth insulating film 108 in the end region P2. The sixth insulating film 109 may be configured as an inorganic insulating film made of silicon nitride (SiN) or silicon dioxide (SiO₂), and is preferred to have about 50 nm to 1000 nm in thickness. The sixth insulating film 109 may have a single layer structure including the single inorganic insulating film, or a layered structure including a plurality of inorganic insulating films.

The sixth insulating film 109 is provided along an inner wall of the opening 108a in the fifth insulating film 108 to configure a depression of the fifth insulating film 108. The sixth insulating film 109 has a depression filled with the adhesive agent for the adhesive layer 211 to configure an adhesive-filling portion 2114.

The adhesive-filling portion 2114 is provided in the depression, penetrating the fifth insulating film 108, of the sixth insulating film 109, and has a surface positioned in the fifth insulating film 108 and covered with the sixth insulating film 109. Even in a case where moisture enters the end of the fifth insulating film 108 configured as a photosensitive resin film, the moisture is less likely to permeate the fifth insulating film 108 toward the scintillator 1b. The sixth insulating film 109 configured as an inorganic insulating film is higher in damp-proofness than the fifth insulating film 108 configured as a photosensitive resin film. The sixth insulating film 109 provided between the fifth insulating film 108 and the scintillator 1b thus achieves higher preventing from moisture penetration into the scintillator 1b from the fifth insulating film 108.

The bias line layer 160 may be formed to have an uneven surface, in which case the bias line layer 160 may not be entirely covered with the fourth insulating film 107 configured as an inorganic insulating film. When moisture enters between the fourth insulating film 107 and the bias line layer 160 having such a defect, the moisture may enter the photodiode 12 from the bias line layer 160 to be likely to cause a flow of leakage current. The fifth insulating film 108 according to the embodiment described above is provided thereon with the sixth insulating film 109 configured as an inorganic insulating film. In comparison to a case where the sixth insulating film 109 is not provided, this configuration improves coverability of the bias line layer 160 and is less likely to allow moisture penetration into the photodiode 12 through the bias line layer 160, to prevent from leakage current.

The adhesive-filling portion 2114 has a bottom of length, along the X axis, which is preferred to be three to ten times of the height (along the Z axis) of the fifth insulating film 108. The opening 108a in the fifth insulating film 108 has width (length along the X axis) which is preferred to be larger at a portion adjacent to the fourth insulating film 107 and be smaller at a portion adjacent to the scintillator 1b. Such a configuration achieves increase in contact area between the adhesive-filling portion 2114 and the sixth insulating film 109 as well as improvement in adhesiveness.

### Application Example 1

The third embodiment described above provides the imaging panel 1-4 including the single adhesive-filling portion 2114. The imaging panel may alternatively have a plurality of adhesive-filling portions 2114 disposed between the boundary of the scintillator region and the adhesive layer 211, as in FIG. 6A.

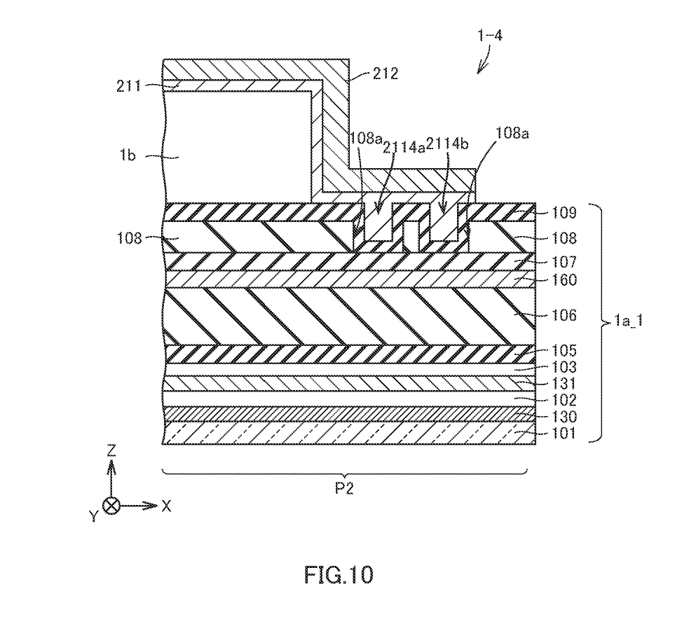

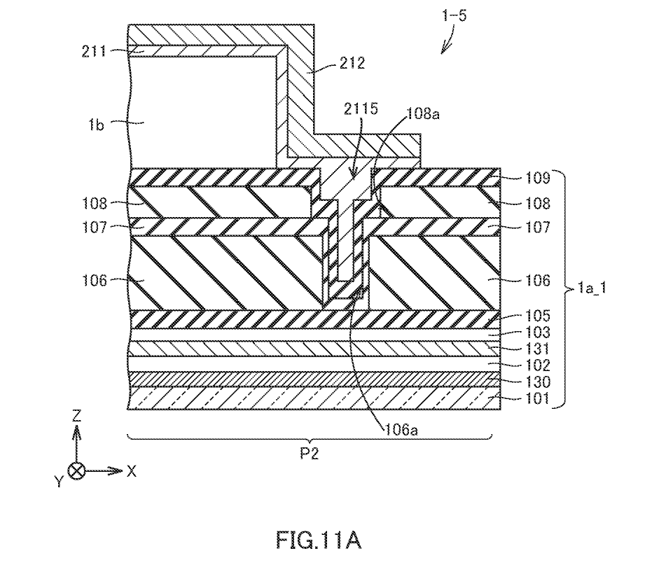

FIG. 10 is a sectional view of the end region P2 in an imaging panel according to the present application example. As shown in FIG. 10, the active matrix substrate 1a_1 in the imaging panel 1-4 according to the present application example 1 includes adhesive-filling portions 2114a and 2114b each structured identically to the adhesive-filling portion 2114 according to the third embodiment and disposed apart from each other.

Such provision of the plurality of adhesive-filling portions 2114a and 2114b in the imaging panel 1-4 achieves higher preventing from moisture penetration into the scintillator 1b from the end of the fifth insulating film 108, in comparison to the configuration according to the third embodiment.

### Application Example 2

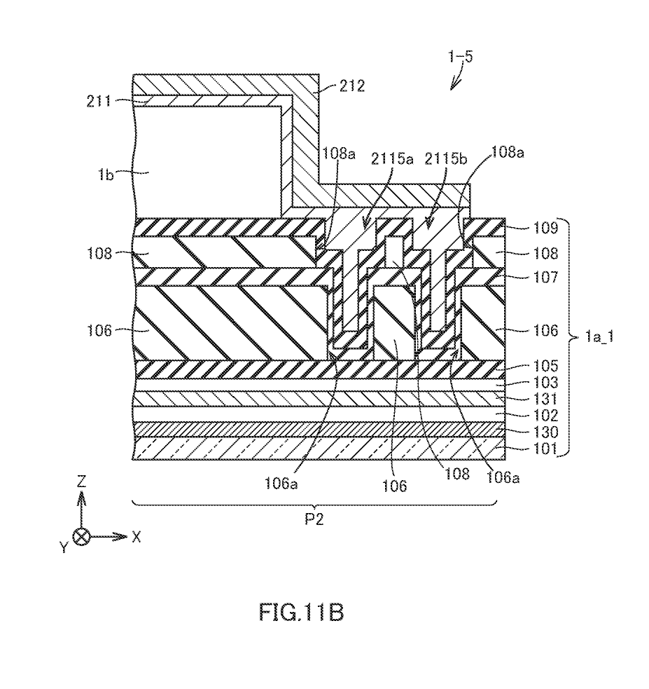

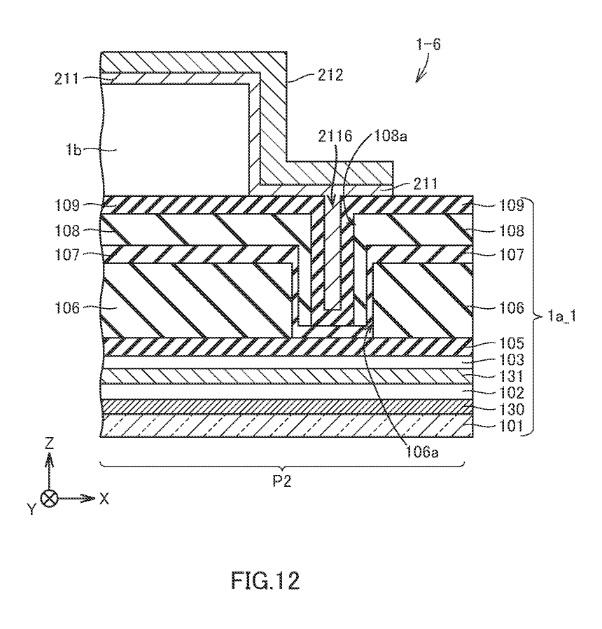

FIG. 11A is a sectional view showing a structure of an adhesive-filling portion in an imaging panel according to the present application example. In FIG. 11A, components identical to those according to the third embodiment are denoted by identical reference signs. Components different from those according to the third embodiment will be mainly described below.

As shown in FIG. 11A, the present application example provides an imaging panel 1-5 including an adhesive-filling portion 2115 that is provided continuously in the sixth insulating film 109, the fifth insulating film 108, the fourth insulating film 107, and the third insulating film 106.

Specifically, in the active matrix substrate 1a_1, the depression of the fourth insulating film 107 is provided along the inner wall of the opening 106a in the third insulating film 106. The opening 108a in the fifth insulating film 108 has opening width larger than width of the depression of the fourth insulating film 107. The depression of the sixth insulating film 109 is provided along the depression of the fourth insulating film 107 and the inner wall of the opening 108a in the fifth insulating film 108. The depression of the sixth insulating film 109 is overlapped with the depression of the fourth insulating film 107, and is provided therein with the adhesive-filling portion 2115.

The adhesive-filling portion 2115 according to the present application example is provided continuously from the sixth insulating film 109 to the third insulating film 106, and has a surface positioned in the third insulating film 106 and covered with two inorganic insulating films, namely, the sixth insulating film 109 and the fourth insulating film 107. Even in a case where moisture enters the end of the third insulating film 106, the moisture is less likely to permeate toward the scintillator 1b. This configuration thus achieves higher preventing from moisture penetration into the scintillator 1b.

### Application Example 3

The application example 2 of the third embodiment described above provides the imaging panel including the single adhesive-filling portion 2115. The imaging panel may alternatively include a plurality of adhesive-filling portions 2115 disposed between the boundary of the scintillator region and the adhesive layer 211, as in FIG. 6A.

FIG. 11B is a sectional view of the end region P2 in an imaging panel according to the present application example. In FIG. 11B, components identical to those according to the application example 2 of the third embodiment are denoted by identical reference signs.

As shown in FIG. 11B, the active matrix substrate 1a_1 in the imaging panel 1-5 according to the present application example includes adhesive-filling portions 2115a and 2115b structured identically to the adhesive-filling portion 2115 according to the application example 2 and disposed apart from each other. Such provision of the plurality of adhesive-filling portions 2115a and 2115b achieves higher preventing from moisture penetration into the scintillator 1b from the ends of the fifth insulating film 108 and the third insulating film 106, in comparison to the configuration according to the application example 2.

### Application Example 4

FIG. 12 is a sectional view showing a structure of an adhesive-filling portion in an imaging panel according to the present application example. As shown in FIG. 12, in the active matrix substrate 1a_1 included in an imaging panel 1-6 according to the present application example, the fifth insulating film 108 covers the inner wall, except the bottom, of the depression of the fourth insulating film 107 penetrating the third insulating film 106, and the opening 108a in the fifth insulating film 108 is disposed in the depression of the fourth insulating film 107. The depression of the sixth insulating film 109 is provided along the inner wall of the opening 108a in the fifth insulating film 108, to configure an adhesive-filling portion 2116.

The adhesive-filling portion 2116 has a side surface positioned in the third insulating film 106 and covered with two inorganic insulating films, namely, the sixth insulating film 109 and the fourth insulating film 107, as well as with the fifth insulating film 108. Even in a case where moisture enters the end of the third insulating film 106, the moisture is less likely to permeate toward the scintillator 1b. This configuration thus achieves higher preventing from moisture penetration into the scintillator 1b in comparison to the configuration according to the application example 2.

Although not shown herein, there may alternatively be provided a plurality of adhesive-filling portions 2116 between the boundary of the scintillator region and the adhesive layer 211 so as to be spaced apart from each other, as in FIG. 6A. Such a configuration prevents from moisture penetration into the scintillator 1b more effectively.

The embodiments of the present invention described above are merely exemplified for implementation of the present invention. The present invention should not be limited to the embodiments described above, and can be implemented with appropriate modifications to the above embodiments without departing from the spirit of the present invention.

(1) In the third embodiment described above (FIGS. 9 to 12), the sixth insulating film 109 may further be provided thereon with an organic film (the third flattening film) that is made of the photosensitive resin same as the material for the fifth insulating film 108 and has an opening being smaller or larger than the depression of the sixth insulating film 109 and filled with the adhesive agent for the adhesive layer 211 to configure an adhesive-filling portion.

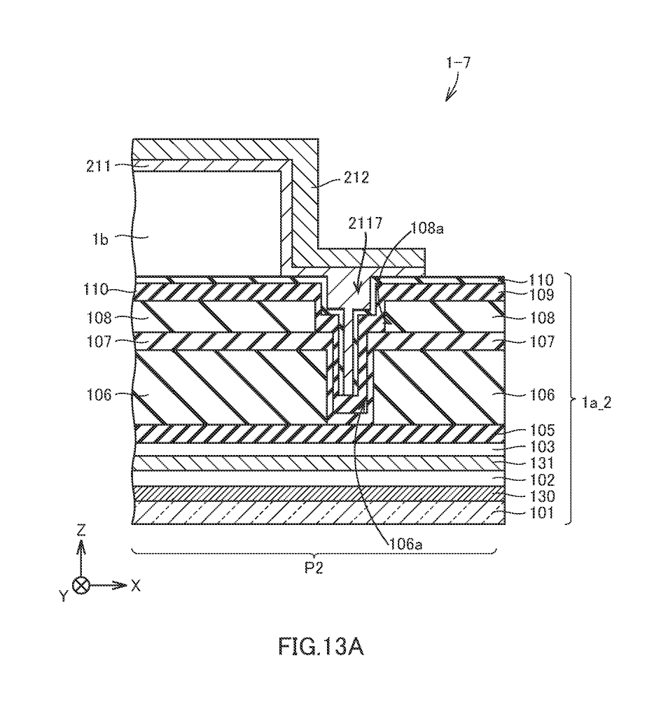

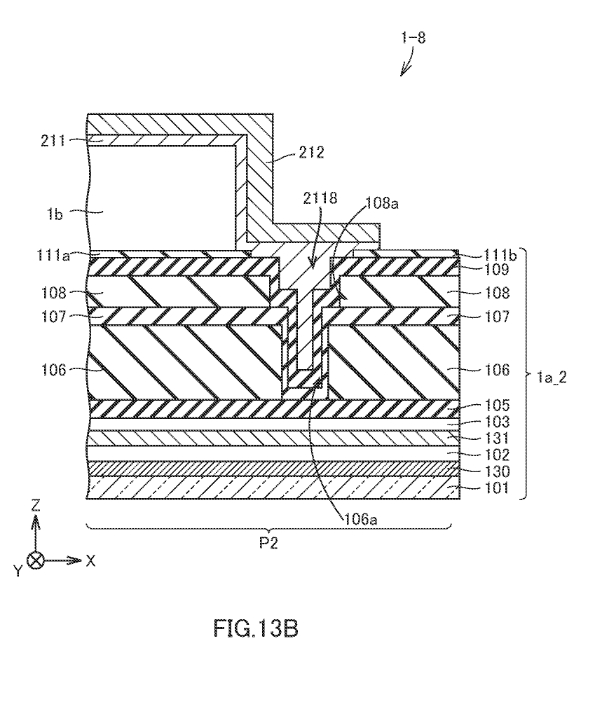

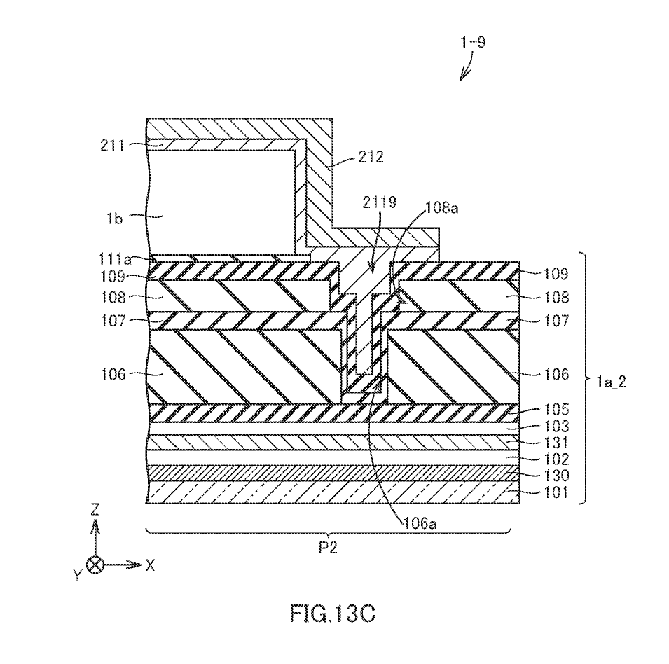

FIGS. 13A and 13B are sectional views each showing a structure of the imaging panel in FIG. 11A provided with the organic film.

FIG. 13A shows an imaging panel 1-7 including an active matrix substrate 1a_2 that has an organic film 110 provided on the sixth insulating film 109. The organic film 110 is provided along a side surface, except a bottom, of the depression of the sixth insulating film 109, and is separated in the depression of the sixth insulating film 109. The organic film 110 accordingly has an opening disposed in the depression of the sixth insulating film 109. The opening in the organic film 110 is filled with the adhesive agent for the adhesive layer 211 to configure an adhesive-filling portion 2117.

FIG. 13B shows an imaging panel 1-8 including the active matrix substrate 1a_2 that has organic films 111a and 111b disposed on the sixth insulating film 109 without covering the depression of the sixth insulating film 109. The organic film 111a is provided on the sixth insulating film 109 in a region overlapped with the scintillator 1b, whereas the organic film 111b is provided on the sixth insulating film 109 in a region not overlapped with the scintillator 1b. The organic films 111a and 111b are not provided in the depression of the sixth insulating film 109, to configure an opening disposed between the organic film 111a and the organic film 111b on the sixth insulating film 109. The opening between the organic film 111a and the organic film 111b and the depression of the sixth insulating film 109 are filled with the adhesive agent for the adhesive layer 211 to configure an adhesive-filling portion 2118.

The imaging panel 1-8 shown in FIG. 13B may alternatively not include the organic film 111b. As shown in FIG. 13C, the organic film 111a may be disposed on the sixth insulating film 109 only in the region overlapped with the scintillator 1b. In this case, the depression of the sixth insulating film 109 is filled with the adhesive agent for the adhesive layer 211 to configure an adhesive-filling portion 2119.

Each of the adhesive-filling portions 2117 to 2119 according to the present modification example is provided continuously in the organic film, the sixth insulating film 109, the fifth insulating film 108, the fourth insulating film 107, and the third insulating film 106. The organic film provided on the sixth insulating film 109 in the region overlapped with the scintillator 1b, that is, a bottom surface of the scintillator 1b, may promote crystal growth of the scintillator 1b.

Although not shown herein, the structure of each of the imaging panels shown in FIGS. 9, 10, 11B, and 12 may include the organic film described above disposed on the sixth insulating film 109 in the region overlapped with the scintillator 1b, that is, the bottom surface of the scintillator 1b.

(2) Each of the fifth insulating film 108 and the third insulating film 106 according to any one of the first to third embodiments may be made of a positive or negative photosensitive resin material.

1. An imaging panel comprising:
an active matrix substrate having a pixel region provided with a plurality of pixels each including a photoelectric conversion element;
a scintillator provided on a surface of the active matrix substrate and configured to convert an X-ray to scintillation light;
a damp-proof material covering the active matrix substrate and the scintillator; and
an adhesive layer bonding the damp-proof material to the scintillator and the active matrix substrate; wherein
the active matrix substrate includes a first flattening film provided inside and outside the pixel region and configured as a photosensitive resin film, and
an adhesive-filling portion provided in a planar view between the adhesive layer and a boundary of a scintillator region provided with the scintillator, penetrating from the surface of the active matrix substrate to the first flattening film, and filled with a material same as a material for the adhesive layer.

2. The imaging panel according to claim 1, wherein
the active matrix substrate further includes a first inorganic film provided inside and outside the pixel region and disposed on a surface, not facing the scintillator, of the first flattening film, and
the first inorganic film is provided continuously from the pixel region to a position of the adhesive-filling portion.

3. The imaging panel according to claim 2, wherein
the active matrix substrate further includes a second flattening film provided on a surface, not facing the first flattening film, of the first inorganic film, and configured as a photosensitive resin film,
the first inorganic film has a recess penetrating the second flattening film, and
the adhesive-filling portion penetrates the first flattening film and is provided continuously to the recess.

4. The imaging panel according to claim 2, wherein
the active matrix substrate further includes a second flattening film provided on a surface, not facing the first flattening film, of the first inorganic film, and configured as a photosensitive resin film,
the first inorganic film has a recess penetrating the second flattening film,
the first flattening film covers at least a portion, disposed adjacent to the scintillator region, in an inner wall of the recess of the first inorganic film, and
the adhesive-filling portion penetrates the first flattening film and is provided continuously to the recess of the first inorganic film.

5. The imaging panel according to claim 2, wherein
the active matrix substrate further includes
a second flattening film provided on a surface, not facing the first flattening film, of the first inorganic film, and configured as a photosensitive resin film, and
a second inorganic film provided on a surface, facing the scintillator, of the first flattening film,
the first inorganic film has a first recess penetrating the second flattening film,
the second inorganic film has a second recess penetrating the first flattening film and covering an inner wall of the first recess, and
the adhesive-filling portion is provided in the second recess of the second inorganic film.

6. The imaging panel according to claim 2, wherein
the active matrix substrate further includes a second inorganic film provided on a surface, facing the scintillator, of the first flattening film,
the second inorganic film has a recess penetrating the first flattening film, and
the adhesive-filling portion is provided in the recess of the second inorganic film.

7. The imaging panel according to claim 6, wherein
the active matrix substrate further includes
a second flattening film provided to oppose the first flattening film with the first inorganic film being interposed therebetween, and configured as a photosensitive resin film, and
a metal film provided between the second flattening film and the first inorganic film, and
the metal film is connected to an element provided in the pixel region.

8. The imaging panel according to claim 2, wherein
the active matrix substrate further includes
a second flattening film provided on a surface, not facing the first flattening film, of the first inorganic film, and configured as a photosensitive resin film, and
a second inorganic film provided on a surface, facing the scintillator, of the first flattening film,
the first inorganic film has a first recess penetrating the second flattening film,
the first flattening film has a second recess covering at least a portion adjacent to the scintillator region and a portion distant from the scintillator region, in an inner wall of the first recess,
the second inorganic film has a third recess covering an inner wall of the second recess, and
the adhesive-filling portion is provided in the third recess.

9. The imaging panel according to claim 5, wherein
the active matrix substrate further includes a third flattening film provided between the second inorganic film and the scintillator, and configured as a photosensitive resin film, and
the third flattening film is disposed at least on the second inorganic film at a position overlapped in a planar view with the scintillator.

10. The imaging panel according to claim 1, wherein the adhesive-filling portion is provided continuously along an outer periphery of the scintillator region.

11. The imaging panel according to claim 1, wherein the imaging panel includes a plurality of adhesive-filling portions configured identically to the adhesive-filling portion, and the adhesive-filling portions are disposed apart from each other in a direction perpendicular to a side of an outer periphery of the scintillator region.
